(19) United States
(12) Patent Application Publication
(10) Pub. No.: US 2009/0159941 A1
(43) Pub. Date: Jun. 25, 2009

(54) CMOS IMAGE SENSOR AND METHOD FOR FABRICATING THE SAME

(75) Inventor: Sang Tae MOON, Busan (KR)

Correspondence Address: Workman Nydegger;1000 Eagle Gate Tower, 60 East South Temple, Salt Lake City, UT, 84111, US

(73) Assignee: DONGBU HITEK CO., LTD., Seoul (KR)

(21) Appl. No.: 12/254,321

(22) Filed: Oct. 20, 2008

(30) Foreign Application Priority Data
Dec. 24, 2007 (KR) 10-2007-0136296

(51) Int. Cl. H01L 27/146; H01L 31/18

(52) U.S. Cl. 257/292; 438/73; 257/E27.133

(57) ABSTRACT

A complementary metal oxide silicon (CMOS) image sensor and a method for fabricating the same. In one example embodiment, a CMOS image sensor includes a substrate, a first dielectric film, a plurality of metal patterns, a second dielectric film, a plurality of via holes, a plurality of metal wires, a plurality of silicon oxide films, a plurality of trenches, and a plurality of photo diodes. The first dielectric film is formed on the substrate. The metal patterns are formed on the first dielectric film. The second dielectric film is formed on the first dielectric film and on the metal patterns. The via holes are formed through the second dielectric film. The metal wires are each formed in one of the via holes. The silicon oxide films are formed on the second dielectric film. The trenches are formed between the silicon oxide films. The photo diodes are formed in the trenches.

### CROSS-REFERENCE TO A RELATED APPLICATION

This application claims the benefit of Korean Patent Application No. 10-2007-0136296, filed on Dec. 24, 2007 which is hereby incorporated by reference as if fully set forth herein.

### BACKGROUND

1. Field of the Invention

Embodiments of the present invention relate to a complementary metal oxide silicon (CMOS) image sensor and a method for fabricating the same.

2. Description of the Related Art

Generally, an image sensor is a semiconductor device for converting an optical image into an electric signal. Image sensors may generally be classified as charge coupled device (CCD) image sensors and CMOS image sensors. A CMOS image sensor includes a photo diode unit for sensing light and a CMOS logic circuit unit for converting the light sensed by the photo diode unit into electric data signals. In general, the more light that is received by the photo diode, the higher the photo sensitivity of the image sensor.

Photo sensitivity can be increased by increasing the ratio of the photo diode area to the entire image sensor area, also known as the fill factor of the image sensor. Photo sensitivity can also be increased by focusing light incent on the non-photo diode region of the image sensor onto the photo diode. For example, a convex micro lens formed from a material that is highly transmissive to light can be formed at the top of the photo diode to bend the path of incident light such that an increased amount of light can be focused on the photo diode. Using this convex micro lens, light parallel to the optical axis of the micro lens is refracted by the micro lens, resulting in the light being focused at a fixed position on the optical axis.

Conventional image sensors generally include a photo diode, an interlayer dielectric layer, a color filter, and a micro lens. The photo diode senses light and converts the light into an electric signal. The interlayer dielectric layer insulates respective metal wires from each other. The color filter represents the three primary colors of light, namely, red (R), green (G), and blue (B). The micro lens focuses light onto the photo diode.

In recent years, efforts have been made to locate the photo diode at the upper part of a CMOS image sensor in order to improve the optical characteristics of the CMOS sensor, as described above. FIG. 1 is a view illustrating a prior art CMOS image sensor. With reference to FIG. 1, the prior art CMOS image sensor includes a substrate 10 having a lower structure, a first dielectric film 20 formed on the substrate 10, a plurality of metal patterns 30 formed on the first dielectric film 20, a second dielectric film 70 formed on the metal patterns 30, a plurality of metal wires 40 formed through the second dielectric film 70, a plurality of photo diodes 50 formed on the respective metal wires 40, and amorphous silicon 60 formed on the photo diodes 50. The amorphous silicon 60 is formed on the photo diodes 50 to cover the photo diodes 50 and is then flattened by chemical-mechanical polishing (CMP). The amorphous silicon 60 is used for insulation and channel formation. In generally, however, the amorphous silicon 60 does not satisfactorily insulate the photo diodes 50.

Furthermore, during the CMP process, the removal speed of the amorphous silicon 60 at the edges is faster than that of the amorphous silicon 60 at the center due to the density of the amorphous silicon 60. Consequently, the amorphous silicon 60 is not removed at the center, whereas the amorphous silicon 60 is removed at the edges, with the result that the edge-side photo diodes 50a are damaged.

### SUMMARY OF EXAMPLE EMBODIMENTS

In general, example embodiments of the present invention relate to a complementary metal oxide silicon (CMOS) image sensor and a method for fabricating the same. Some example embodiments of the CMOS image sensor are capable of preventing the damage to photo diodes formed at the upper part of the image sensor.

In one example embodiment, a CMOS image sensor includes a substrate, a first dielectric film, a plurality of metal patterns, a second dielectric film, a plurality of via holes, a plurality of metal wires, a plurality of silicon oxide films, a plurality of trenches, and a plurality of photo diodes. The first dielectric film is formed on the substrate. The substrate has a lower structure. The metal patterns are formed on the first dielectric film. The second dielectric film is formed on the first dielectric film and on the metal patterns. The via holes are formed through the second dielectric film to expose the metal patterns. Each of the metal wires is formed in one of the via holes. The silicon oxide films are formed on the second dielectric film. Each of the trenches is formed between two of the silicon oxide films such that each trench corresponds to one of the metal patterns. Each of the photo diodes is formed in one of the trenches.

In another example embodiment, a method for fabricating a CMOS image sensor includes various acts. First, a first dielectric film is formed on a substrate having a lower structure. Then, a plurality of metal patterns is formed on the first dielectric film. Next, each of a plurality of metal wires is formed on one of the metal patterns. Then, each of a plurality of trenches is formed over one of the metal wires. Finally, each of a plurality of photo diodes is formed in one of the trenches. The metal wires and the trenches are formed by a damascene process.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter. Moreover, it is to be understood that both the foregoing general description and the following detailed description of the present invention are exemplary and explanatory and are intended to provide further explanation of the invention as claimed.

### BRIEF DESCRIPTION OF THE DRAWINGS

Aspects of example embodiments of the present invention will become apparent from the following detailed description of example embodiments given in conjunction with the accompanying drawings, in which:

FIG. 1 is a cross-sectional view of a prior art complementary metal oxide silicon (CMOS) image sensor; and

FIGS. 2-7 are cross-sectional views illustrating various states of fabrication of an example CMOS image sensor.

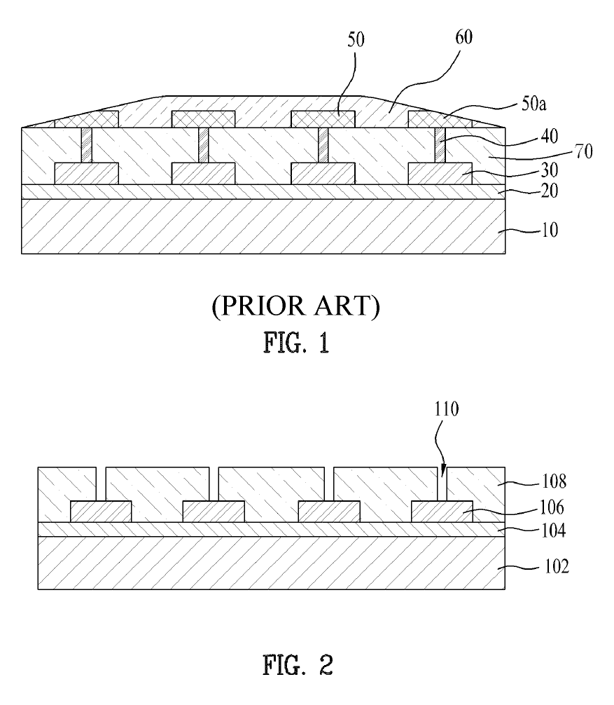

### DETAILED DESCRIPTION OF EXAMPLE EMBODIMENTS

In general, example embodiments of the present invention relate to a complementary metal oxide silicon (CMOS) image sensor and a method for fabricating the same. In the following detailed description of the embodiments, reference will now be made in detail to specific embodiments of the present invention, examples of which are illustrated in the accompanying drawings. Wherever possible, the same reference numbers will be used throughout the drawings to refer to the same or like parts. These embodiments are described in sufficient detail to enable those skilled in the art to practice the invention. Other embodiments may be utilized and structural, logical and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

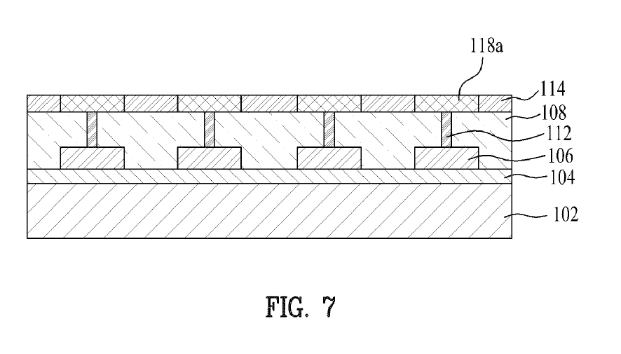

FIGS. 2 to 7 are views illustrating an example CMOS image sensor. With reference first to FIG. 7, the example CMOS image sensor includes a substrate 102, a first dielectric film 104, a plurality of metal patterns 106, a second dielectric film 108, a plurality of via holes 110 (shown in FIG. 2), a plurality of metal wires 112, a plurality of silicon oxide films 114, a plurality of trenches 116 (shown in FIG. 4), and a plurality of photo diodes 118a. The first dielectric film 104 is formed on the substrate 102 having a lower structure (not shown). The metal patterns 106 are formed on the first dielectric film 104. The second dielectric film 108 is formed on the first dielectric film 104 and the metal patterns 106. The via holes 110 (shown in FIG. 2) are formed through the second dielectric film 108 to expose the metal patterns 106. Each metal wire 112 is formed in one of the via holes 110. The silicon oxide films 114 are formed on the second dielectric film 108. Each trench 116 (shown in FIG. 4) is formed between two of the silicon oxide films 114 such that each trench 116 corresponds to one of the metal patterns 106. The photo diodes 118a are formed by etching a photo diode metal layer such that the photo diodes 118a are left only in the trenches 116.

With reference now to FIGS. 2-7, an example method of fabricating the above-described example CMOS image sensor will be described.

With reference first to FIG. 2, a first dielectric film 104 is formed on a substrate 102 having a lower structure (not shown), such as a transistor and/or a capacitor. The first dielectric film 104 may be deposited by plasma enhanced chemical vapor deposition (PECVD). The first dielectric film 104 may be made of an inorganic or organic dielectric material, such as silicon oxide (SiOn) or silicon nitride (SiNx). Subsequently, a plurality of metal patterns 106 is formed on the first dielectric film 104. The metal patterns 106 may be formed on the first dielectric film 104 by depositing a metal layer on the entire surface of the first dielectric film 104 by using a deposition method, such as sputtering, and patterning the metal layer by a photo and etching process using a mask. The metal layer may be made of molybdenum (Mo), titanium (Ti), copper (Cu), aluminum neodymium (AlNd), aluminum (Al), chromium (Cr), molybdenum (Mo) alloy, copper (Cu) alloy, aluminum (Al) alloy, or some combination thereof. The metal layer may be configured in a single layer structure or a double layer structure.

Subsequently, a second dielectric film 108 is formed on the first dielectric film 104, including the metal patterns 106. The second dielectric film 108 may be deposited by PECVD and may be made of an inorganic or organic dielectric material. Next, a plurality of via holes 110 is formed through the second dielectric film 108 at regions corresponding to the metal patterns 106 in order to expose the metal patterns 106. The via holes 110 may be formed by a photo and etching process using a mask. Each via hole 110 may have a depth between about 500 Å and about 1500 Å.

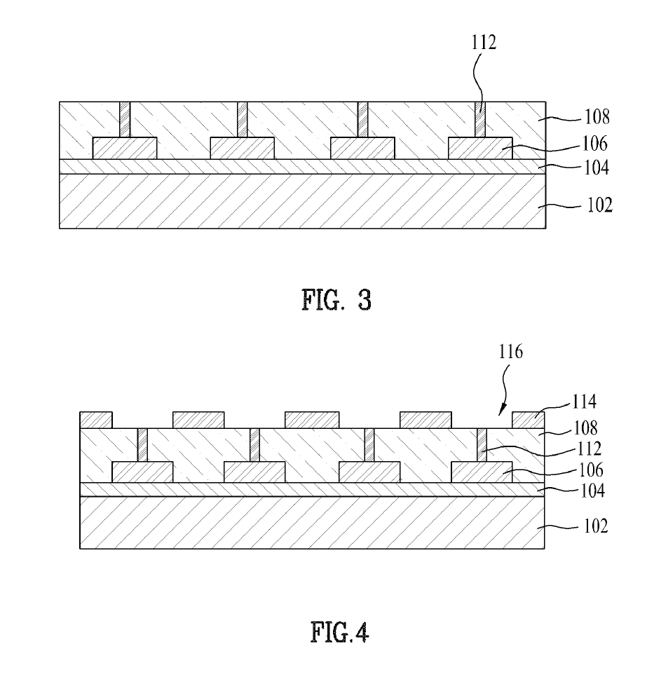

With reference now to FIG. 3, a plurality of metal wires 112 is formed in the respective via holes 110 (shown in FIG. 2). The plurality of metal wires 112 may be formed by forming a metal wire layer on the second dielectric film 108 such that the respective via holes 110 (shown in FIG. 2) are filled with the metal wire layer. The metal wire layer may be formed by electro plating. Subsequently, the metal wire layer may be etched, by chemical-mechanical polishing (CMP) or etchback, such that the second dielectric film 108 is exposed to form a plurality of metal wires 112 in the via holes 110.

With reference now to FIG. 4, a silicon oxide film is formed on the metal wires 112 and on the second dielectric film 108. The silicon oxide film may be deposited by plasma enhanced chemical vapor deposition (PECVD), atomic layer deposition, or heat diffusion, and may be made of an inorganic or organic dielectric material. Subsequently, a plurality of trenches 116 is formed in the silicon oxide film at regions corresponding to the respective metal patterns 106, resulting in a plurality of silicon oxide films 114. The trenches 116 may be formed by performing a photo and etching process using a mask on the silicon oxide film.

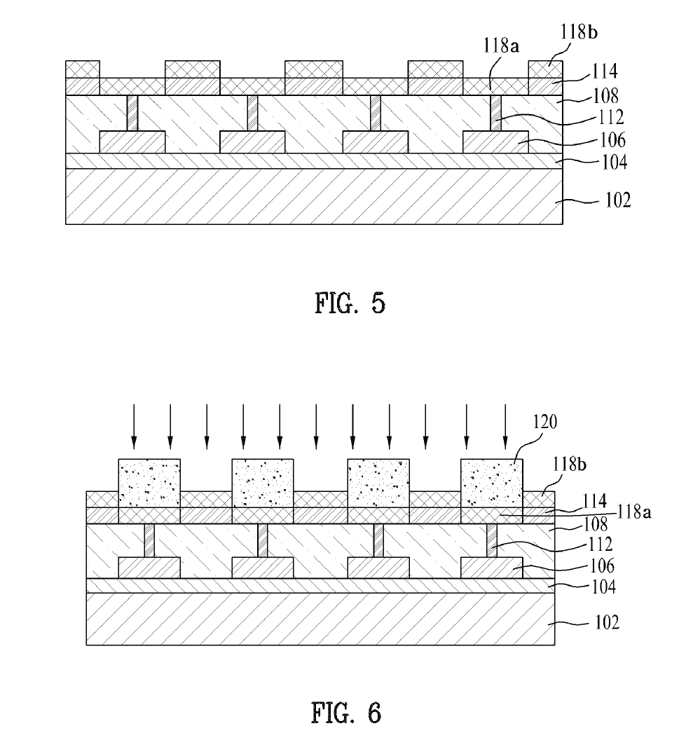

With reference now to FIG. 5, photo diode metal layers 118a and 118b are next formed in the trenches 116 and on the silicon oxide films 114, respectively. The photo diode metal layers 118a and 118b may be formed by using a deposition method such as sputtering. The photo diode metal layers 118 may be made of chromium (Cr), titanium (Ti), or some combination thereof.

With reference now to FIG. 6, photo resists 120 may be formed in the respective trenches 116 on the photo diode metal layers 118a. The photo resists 120 serve as a mask to remove the photo diode metal layers 118b without removing the photo diodes 118a. Subsequently, the photo diode metal layers 118b are etched using the photo resists 120 as a mask such that the silicon oxide films 114 are exposed. Then, the photo resists 120 are then removed to expose the photo diodes 118a. The photo diode metal layers 118b may be etched by wet etching or dry etching.

In the above-described example CMOS image sensor, the photo diodes 118a are formed by a damascene process to form the trenches 116, after the formation of the via holes 110, and then the unnecessary photo diode metal layers 118b are removed by an etching process, whereby the damage to the photo diodes 118a at the surfaces thereof is reduced, and the photo diodes 118a have a uniform thickness. As apparent from the above description, during the fabrication of the example CMOS image sensor the photo diodes are formed by a damascene process, and then the unnecessary photo diode metal layers are removed by an etching process. Consequently, the example fabrication method can reduce the damage to the photo diodes and result in formation of the photo diodes with a uniform thickness.

Although example embodiments of the present invention have been shown and described, various modifications and variations might be made to these example embodiments. The scope of the invention is therefore defined in the following claims and their equivalents.

What is claimed is:

1. A complementary metal oxide silicon (CMOS) image sensor comprising:
a first dielectric film formed on a substrate having a lower structure;
a plurality of metal patterns formed on the first dielectric film;
a second dielectric film formed on the first dielectric film and on the metal patterns;
a plurality of via holes formed through the second dielectric film to expose the metal patterns;
a plurality of metal wires each formed in one of the via holes;
a plurality of silicon oxide films formed on the second dielectric film;
a plurality of trenches each formed between two of the silicon oxide films such that each trench corresponds to one of the metal patterns; and
a plurality of photo diodes each formed in one of the trenches.

2. The CMOS image sensor according to claim 1, wherein the photo diodes are made of chromium (Cr), titanium (Ti), or some combination thereof.

3. The CMOS image sensor according to claim 1, wherein the photo diodes have a thickness between about 100 Å and about 2000 Å.

4. The CMOS image sensor according to claim 1, wherein the via holes have a depth between about 500 Å and about 1500 Å.

5. A method for fabricating a CMOS image sensor, comprising:
forming a first dielectric film on a substrate having a lower structure;
forming a plurality of metal patterns on the first dielectric film;
forming each of a plurality of metal wires on one of the metal patterns;
forming each of a plurality of trenches over one of the metal wires; and
forming each of a plurality of photo diodes in one of the trenches,
wherein the metal wires and the trenches are formed by a damascene process.

6. The method according to claim 5, wherein forming the plurality of metal wires includes:
forming a second dielectric film on the first dielectric film and the metal patterns;
forming a plurality of via holes through the second dielectric film at regions corresponding to the metal patterns;
forming a metal wire layer such that the respective via holes are filled with the metal wire layer; and
etching the metal wire layer to form the plurality of metal wires.

7. The method according to claim 6, wherein forming the photo diodes includes:
forming a silicon oxide film on the second dielectric film and the metal wires;
etching the silicon oxide film such that the trenches are formed at regions where the photo diodes will be formed;
forming a photo diode metal layer on the silicon oxide film and in the respective trenches;
forming photo resists on the photo diode metal layer formed in the respective trenches;
etching the photo diode metal layer to expose the silicon oxide film, and
removing the photo resists to expose the photo diodes.

8. The method according to claim 5, wherein the photo diodes are made of chromium (Cr), titanium (Ti), or some combination thereof.

9. The method according to claim 5, wherein the photo diodes have a thickness between about 100 Å and about 2000 Å.

10. The method according to claim 6, wherein the via holes have a depth between about 500 Å and about 1500 Å.
